(19) United States
(12) Patent Application Publication
(10) Pub. No.: US 2006/0197186 A1
(43) Pub. Date: Sep. 7, 2006

(54) LIGHT VALVE AND METHOD FOR MANUFACTURING THE SAME

(76) Inventor: Yang-Chang Chien, Shenzhen (CN)

Correspondence Address: NORTH AMERICA INTELLECTUAL PROPERTY CORPORATION, P.O. BOX 506, MERRIFIELD, VA, 22116, US

(21) Appl. No.: 11/306,626

(22) Filed: Jan. 4, 2006

(30) Foreign Application Priority Data
Jan. 19, 2005 (CN) 200510032936.3

(51) Int. Cl. H01L 27/102

(52) U.S. Cl. 257/583

(57) ABSTRACT

This invention relates to a light valve (100) and a method for manufacturing the same. The light valve includes a substrate (10), a first comb-shaped electrode (40) and a second comb-shaped electrode (50). The substrate has a first through hole (13). The first comb-shaped electrode is formed on the substrate and has a number of first electrode teeth (42) and a hole portion (41) define a second through hole (44) configured for aligning with the first through hole. The second comb-shaped electrode has a number of second electrode teeth (52). The first and second electrode teeth are configured in a staggered fashion and at least one of the first and second comb-shaped electrodes is movable toward to the other.

### FIELD OF THE INVENTION

The invention relates generally to light valves, and more particularly, to a light valve for image display devices and a method for manufacturing the same.

### DESCRIPTION OF RELATED ART

Light valves have been increasingly used in various image display devices. For example, a liquid crystal display (LCD) device utilizes liquid crystal as a light valve to regulate the flow of backlight passing therethrough. A projection LCD device includes a light source, a light valve, a screen, an optical filter, and a projection lens. There are two types of light valves which are used for the LCD device. One is a transmission-type liquid crystal light valve for projecting an image on a screen by letting in the light from the light source, and the other is a reflection-type liquid crystal light valve for projecting an image on the screen by reflecting the light from the light source.

In the case of a reflection-type liquid crystal light valve, incident light passes through the space between the reflecting electrodes and is transmitted into the interlayer insulating layer, and then propagates through the interlayer insulating layer by multipath reflections. When this light comes near the transistor, it causes a leakage current as a result of the photoconductive effect, and thus degrades the contrast of the LCD. Besides, the LCD device utilizing the liquid crystal as the light valve, a substantial fraction of the polarized projection beam will be absorbed by the liquid crystal. Therefore, an efficiency of utilization of the light is reduced. In addition, the performance of the liquid crystal is deteriorated after use for a period of time.

What is needed, therefore, is a light valve has a high utilization of light.

### SUMMARY OF THE INVENTION

In one embodiment, a light valve includes a substrate, a first comb-shaped electrode and a second comb-shaped electrode. The substrate has a first through hole. The first comb-shaped electrode is formed on the substrate and has a number of first electrode teeth and a hole portion define a second through hole configured for aligning with the first through hole. The second comb-shaped electrode has a number of second electrode teeth. The first and second electrode teeth are configured in a staggered fashion and at least one of the first and second comb-shaped electrodes is movable toward to the other.

In another embodiment, a method for manufacturing a light valve includes the steps: providing a substrate with a first through hole defined therein; forming a sacrificing layer on the substrate; forming a metal layer on the sacrificing layer; forming the metal layer into first and second comb-shaped electrodes in a manner such that the first comb-shaped electrode has a hole portion and a number of first electrode teeth, the hole portion having a second through hole aligned with the first through hole, and the second comb-shaped electrode has a number of second electrode teeth, the first and second electrode teeth being configured in a staggered fashion; and removing the sacrificing layer, thereby obtaining the light valve.

Advantages and novel features of the present light valve will become more apparent from the following detailed description of preferred embodiments when taken in conjunction with the accompanying drawings.

### BRIEF DESCRIPTION OF DRAWINGS

Many aspects of the present light valve and the method for manufacturing the same can be better understood with reference to the following drawings. The components in the drawings are not necessarily to scale, the emphasis instead being placed upon clearly illustrating the principles of the present light valve and the method for manufacturing the same.

FIG. 1 is a schematic view of a substrate of a light valve in accordance with a preferred embodiment;

FIG. 2 is similar to FIG. 1, but showing an opaque layer formed on the substrate of FIG. 1;

FIG. 3 is similar to FIG. 2, but showing a first through hole defined on the opaque layer of FIG. 2;

FIG. 4 is similar to FIG. 3, but showing a sacrificing layer formed on the optical shield layer of FIG. 3;

FIG. 5 is similar to FIG. 4, but showing a metal layer formed on the sacrificing layer of FIG. 4;

FIG. 6 is similar to FIG. 5, but showing the metal layer is formed into first and second comb-shaped electrodes;

FIG. 7 is similar to FIG. 6, but showing a light valve after removing the sacrificing layer of FIG. 6;

FIG. 8 is a top view of FIG. 7, showing the light valve is in an opened state;

FIG. 9 is a schematic view showing the light valve is in a closed position;

FIG. 10 is similar to FIG. 9, but viewed from another aspect; and

FIG. 11 is a flowchart showing a method for manufacturing the light valve in accordance with the preferred embodiment.

Corresponding reference characters indicate corresponding parts throughout the several views. The exemplifications set out herein illustrate at least one preferred embodiment of the present invention, in one form, and such exemplifications are not to be construed as limiting the scope of the invention in any manner.

### DETAILED DESCRIPTION

Reference will now be made to the drawings to describe embodiments of the present invention, in detail.

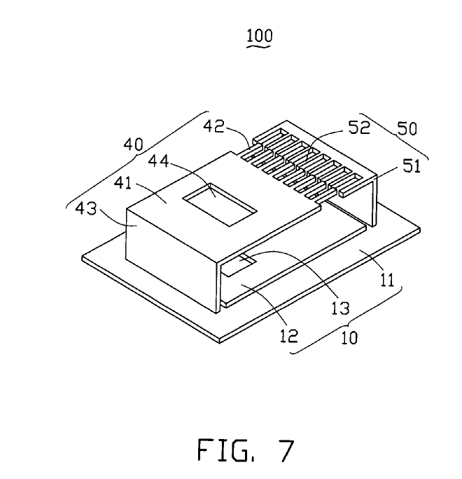

Referring initially to FIG. 7, a light valve 100 according to an exemplary embodiment is shown. In the present embodiment, the light valve 100 includes a substrate 10, a first comb-shaped electrode 40 and a second comb-shaped electrode 50. The substrate 10 further includes a base plate 11, an opaque layer 12 and a first through hole 13.

The first comb-shaped electrode 40 is formed on the substrate 10. The first comb-shaped electrode 40 has a number of first electrode teeth 42, a hole portion 41 define a second through hole 44 configured for aligning with the first through hole 13, and a first bendable portion 43. The first bendable portion 43 extends perpendicularly from the substrate 10. The hole portion 41 is connected with the first bendable portion 43 and is configured to be substantially parallel to the substrate 10. The first electrode teeth 42 are connected with the hole portion 41 and face the second comb-shaped electrode 50.

The second comb-shaped electrode 50 has a number of second electrode teeth 52, a second bendable portion 51. The second bendable portion 51 extends perpendicularly from the substrate 10. The second electrode teeth 52 are connected with the second bendable portion 51 configured to be substantially parallel to the substrate 10, and face the first electrode teeth 42. The first electrode teeth 42 and the second electrode teeth 52 are configured in a staggered fashion and at least one of the first 40 and second 50 comb-shaped electrodes is movable toward to the other.

The second through hole 44 is aligned with the first through hole 13. The first 13 and second 44 through holes cooperatively define a vertical passage (not labeled) for allowing incident light beams to pass therethrough. By an electrostatic force action, a space between the first electrode teeth 42 and the second electrode teeth 52 is adjusted for controlling the channel size that determines brightness of output light beams.

The material of the base plate 11 is made of a transparent material, such as silicon oxide. The material of the opaque layer 12 is a metal selected from alumina, copper and iron. The first comb-shaped electrode 40 and the second comb-shaped electrode 50 are made of electrically conductive and opaque materials, such as metal selected from alumina, copper and iron. In the illustrated embodiment, the first bendable portion 43 is configured to be flexible. The second bendable portion 51 is changed to be inflexible (i.e. rigid). Alternatively, the first 43 and second 51 bendable portions could be both configured to be flexible.

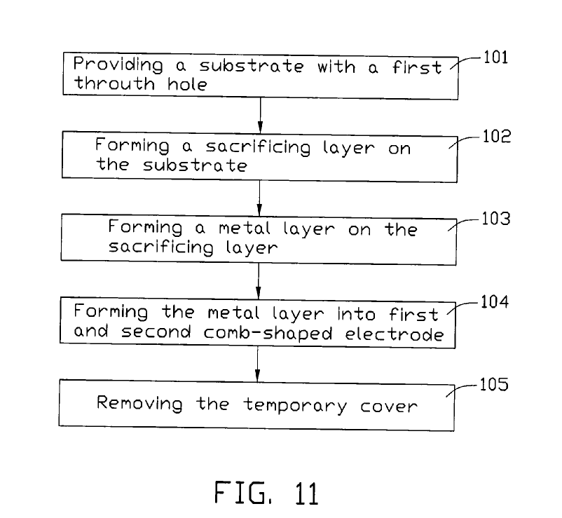

Referring to FIG. 11, this illustrates a method for manufacturing the light valve according to an exemplary embodiment. The method includes the steps of: step 101: providing a substrate with a first through hole defined therein; step 102: forming a sacrificing layer on the substrate; step 103: forming a metal layer on the sacrificing layer; step 104: forming the metal layer into first and second comb-shaped electrodes in a manner such that the first comb-shaped electrode has a hole portion and a number of first electrode teeth, the hole portion having a second through hole aligned with the first through hole, and the second comb-shaped electrode has a number of second electrode teeth, the first and second electrode teeth being configured in a staggered fashion; step 105: removing the sacrificing layer, thereby obtaining the light valve. The method is described in detail as follows:

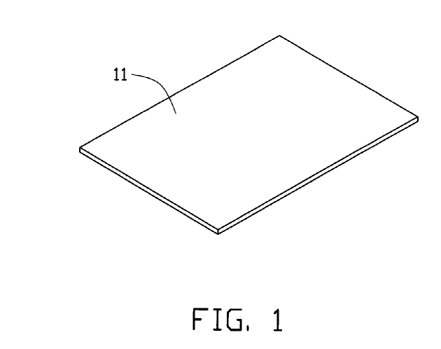

Initially, referring to FIG. 1, a base plate 11 is provided. The base plate 11 is made of a transparent material, such as silicon oxide.

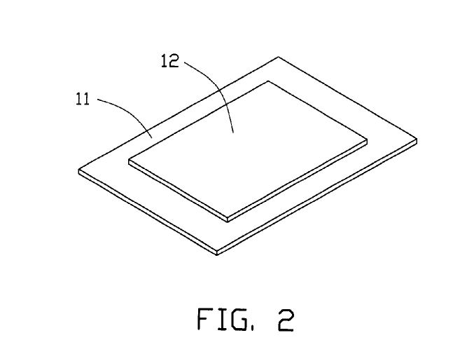

Referring to FIG. 2, an opaque layer 12 is deposited on the base substrate 11. The opaque layer 12 is made of a metal selected from the group consisting of alumina, copper and iron.

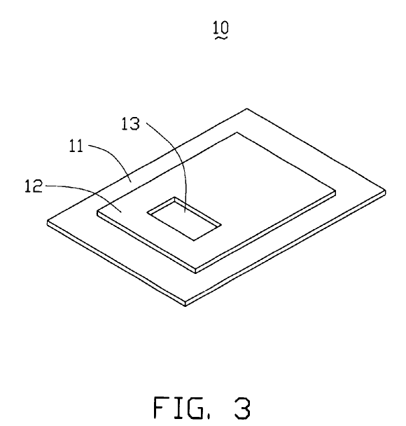

Referring to FIG. 3, a substrate 10 has a first through hole 13 defined in the opaque layer 12 by a photolithography method. The photolithography method includes the steps of coating a photoresist layer on the opaque layer 12; exposing the photoresist layer using a mask and developing the photoresist layer to form a hole pattern on the photoresist layer; etching the opaque layer 12 to define a hole 13 in the opaque layer 12; removing the remaining portions of the photoresist layer.

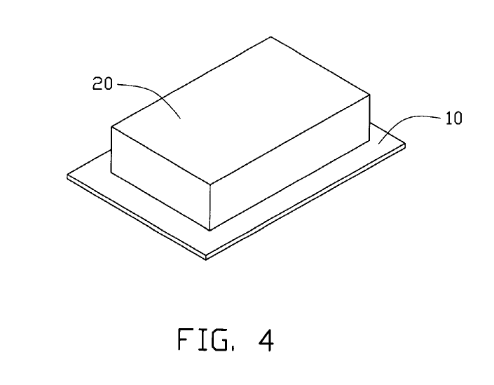

Referring to FIG. 4, a sacrificing layer 20 is formed on the substrate 10 and substantially cover the opaque layer 12. The material of the sacrificing layer 20 is a semiconductor selected from the group consisting of silicon, silicon carbide, silicon nitride, etc. A thickness of the sacrificing layer 20 is in the range of 10 micrometers to 1000 micrometers. Preferably, the thickness of the sacrificing layer 20 is in the range from 50 micrometers to 500 micrometers.

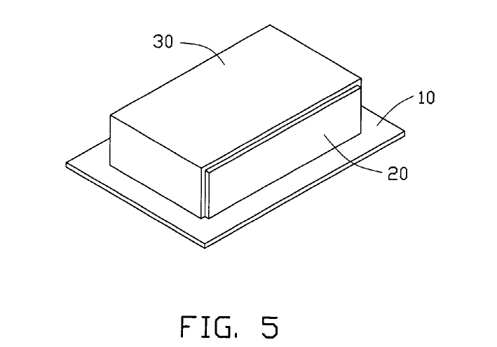

Referring to FIG. 5, a metal layer 30 is deposited on a top surface and two side surfaces of the sacrificing layer 20. The material of the metal layer 30 is selected from the group consisting of copper, alumina and iron, etc.

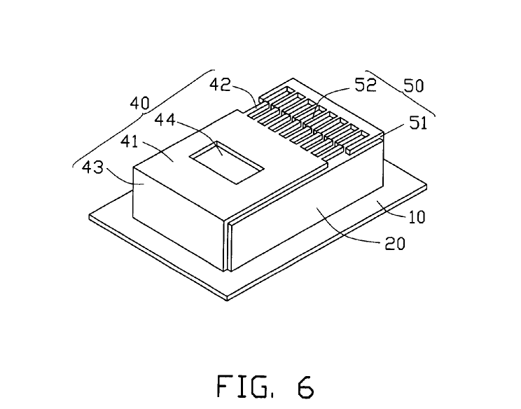

By a photolithography method, the metal layer 30 is formed into comb-shaped electrodes 40, 50 as shown in FIG. 6. The comb-shaped electrodes have a first comb-shaped electrode 40 and a second comb-shaped electrode 50. The first comb-shaped electrode 40 is formed on the substrate 10. The first comb-shaped electrode 40 has a number of first electrode teeth 42, a hole portion 41 define a second through hole 44 and a first bendable portion 43. The first bendable portion 43 extends perpendicularly from the substrate 10. The hole portion 41 is connected with the first bendable portion 43 and is configured to be substantially parallel to the substrate 10. The first electrode teeth 42 are connected with the hole portion 41 and face the second comb-shaped electrode 50.

The second comb-shaped electrode 50 has a number of second electrode teeth 52, a second bendable portion 51. The second bendable portion 51 extends perpendicularly from the substrate 10. The second electrode teeth 52 are connected with the second bendable portion 51 configured to be substantially parallel to the substrate 10, and face the first electrode teeth 42. The first electrode teeth 42 and the second electrode teeth 52 are configured in a staggered fashion and at least one of the first 40 and second 50 comb-shaped electrodes is movable toward to the other.

The first comb-shaped electrode 40 and the second comb-shaped electrode 50 are made of electrically conductive and opaque materials, such as a metal selected from alumina, copper and iron. In the illustrated embodiment, the first bendable portion 43 is configured to be flexible. The second bendable portion 51 is changed to be inflexible (i.e. rigid). Alternatively, the first 43 and second 51 bendable portions could be both configured to be flexible.

Referring to FIG. 7, the sacrificing layer 20 is removed by an etching method. Thereby, a light valve is obtained.

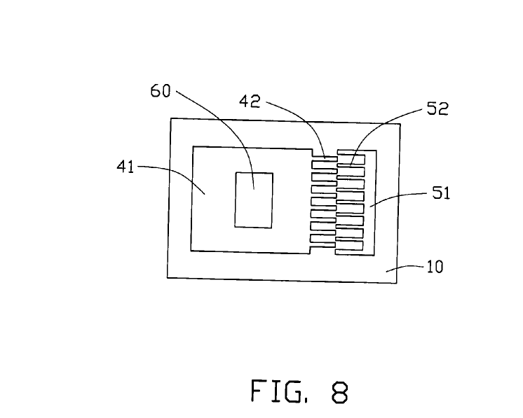

Referring also to FIG. 8, the light valve 100 is in an opened state. Due to the absence of the electrostatic force, the first electrode teeth 42 is spaced apart a distance from the second electrode teeth 52. As such, the first through hole 13 is vertically aligned with the second through hole 44, and thereby a vertical passage 60 is defined. Vertically incident light can pass through the light valve via the vertical passage 60. In particular, the maximum light can pass through the light valve.

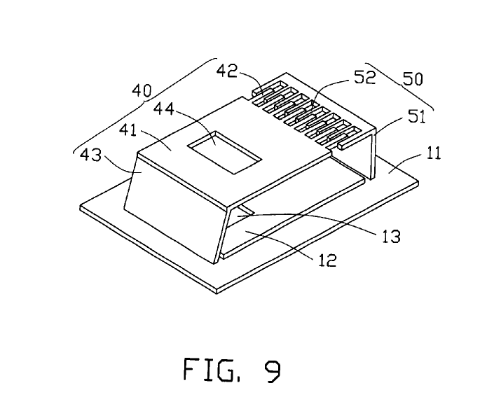

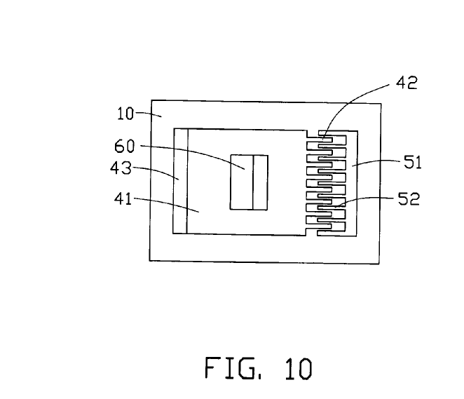

Referring to FIGS. 9 and 10, these figures show the light valve 100 is in a closed state. A voltage is applied between the first 40 and second 50 comb-shaped electrodes, and thereby the first comb-shaped electrode 40 is forced to move toward the second comb-shaped electrode 50 due to the presence of the electrostatic force existing between the first comb-shaped electrode 40 and the second comb-shaped electrode 50. As such, the first through hole 13 is misaligned with the second through hole 44. An opening size of the vertical passage 60 is thus reduced. The opening size of the vertical passage 60 may be adjusted by adjusting the voltage applied between the first 40 and second 50 comb-shaped electrodes. Therefore, the intensity of light passed through the light valve 100 can be regulated by adjusting the opening size of the light passage 60. The present light valve 100 can be used in an image display system at 8 bits/256 grey levels.

Finally, it is to be understood that the above-described embodiments are intended to illustrate rather than limit the invention. Variations may be made to the embodiments without departing from the spirit of the invention as claimed. The above-described embodiments illustrate the scope of the invention but do not restrict the scope of the invention.

What is claimed is:

1. A light valve comprising:
a substrate having a first through hole defined therein;
a first comb-shaped electrode formed on the substrate, the first comb-shaped electrode having a plurality of first electrode teeth and a hole portion define a second through hole configured for aligning with the first through hole; and
a second comb-shaped electrode having a plurality of second electrode teeth, the first and second electrode teeth being configured in a staggered fashion, at least one of the first and second comb-shaped electrode being movable toward to the other so as to misalign the first through hole with the second through hole.

2. The light valve as claimed in claim 1, wherein the first and second comb-shaped electrodes are comprised of metal.

3. The light valve as claimed in claim 2, wherein the metal is selected from the group consisting of copper, alumina and iron.

4. The light valve as claimed in claim 1, wherein the first comb-shaped electrode has a bendable portion and the hole portion connected with the bendable portion.

5. The light valve as claimed in claim 4, wherein the bendable portion extends perpendicularly from the substrate, and the hole portion is configured to be substantially parallel to the substrate.

6. The light valve as claimed in claim 1, wherein the second comb-shaped electrode extends from the substrate.

7. A method for manufacturing a light valve, comprising the steps of:
providing a substrate with a first through hole defined therein
forming a sacrificing layer on the substrate;
forming a metal layer on the sacrificing layer;
forming the metal layer into first and second comb-shaped electrodes in a manner such that the first comb-shaped electrode has a hole portion and a plurality of first electrode teeth, the hole portion having a second through hole aligned with the first through hole, and the second comb-shaped electrode has a plurality of second electrode teeth, the first and second electrode teeth being configured in a staggered fashion; and
removing the sacrificing layer, thereby obtaining the light valve.

8. The method as claimed in claim 7, wherein the first through hole is formed by an etching method.

9. The method as claimed in claim 7, wherein the material of the sacrificing layer is a semiconductor selected from the group consisting of silicon, silicon carbide and silicon nitride.

10. The method as claimed in claim 7, wherein the sacrificing layer is formed by a deposition method.

11. The method as claimed in claim 7, wherein the sacrificing layer is removed by an etching method.

12. The method as claimed in claim 7, wherein the metal layer is formed by a deposition method.

13. The method as claimed in claim 7, wherein the first and second comb-shaped electrodes are made by a photolithographic method.

14. A method for manufacturing a light valve, comprising the steps of:
providing a substrate with a first through hole defined therein; and
forming a first comb-shaped electrode and a second comb-shaped electrode on the substrate;
wherein the first comb-shaped electrode has a hole portion and a plurality of first electrode teeth, the hole portion having a second through hole aligned with the first through hole, and the second comb-shaped electrode has a plurality of second electrode teeth, the first and second electrode teeth being configured in a staggered fashion.

15. The method as claimed in claim 14, wherein the step of forming the first and second comb-shaped electrodes comprising the substeps of:
forming a sacrificing layer on the substrate;
forming a metal layer on the sacrificing layer;
forming the metal layer into first and second comb-shaped electrodes by a photolithography process;
removing the sacrificing layer, thereby obtaining the light valve.

16. The method as claimed in claim 15, wherein the material of the sacrificing layer is a semiconductor selected from the group consisting of silicon, silicon carbide and silicon nitride.

17. The method as claimed in claim 15, wherein the sacrificing layer is formed by a deposition method.

18. The method as claimed in claim 15, wherein the sacrificing layer is removed by an etching method.

19. The method as claimed in claim 15, wherein the metal layer is formed by a deposition method.
